(19) United States
(12) Patent Application Publication
(10) Pub. No.: US 2018/0211750 A1
(43) Pub. Date: Jul. 26, 2018

(54) THREE-DIMENSIONAL INDUCTANCE COIL AND A METHOD FOR PRODUCING THE SAME IN PRINTED CIRCUIT BOARD

(71) Applicant: AKM ELECTRONICS INDUSTRIAL (PANYU) LTD., Guangzhou (CN)

(72) Inventors: Jing Wang, Guangzhou (CN); Simeng Zhu, Guangzhou (CN); Ling Wang, Guangzhou (CN); Hang Yang, Guangzhou (CN)

(73) Assignee: AKM ELECTRONICS INDUSTRIAL (PANYU) LTD., Guangzhou (CN)

(21) Appl. No.: 15/740,623

(22) PCT Filed: Aug. 11, 2015
(86) PCT No.: PCT/CN2015/086589

§ 371 Date: Dec. 28, 2017

(30) Foreign Application Priority Data
Jun. 30, 2015 (CN) 201510385782.X

(51) Int. Cl. H01F 5/00; H01F 27/28; H01F 41/04; H05K 1/16

(52) U.S. Cl. CPC H01F 5/003; H05K 1/165; H01F 41/041; H01F 27/2804

(57) ABSTRACT

A three-dimensional inductance coil and a method for producing the same in printed circuit board are provided. The method comprises the following steps: 1) Drilling through-holes on a twin surface copper-clad laminate bilaterally, to form two rows of through-holes on the twin surface copper-clad laminate; 2) cleaning the interior of through-holes; 3) Copper-plating the walls of the through-holes to form a copper layer thereon; 4) filling the through-holes with copper fully to form the first copper column row and the second copper column row in the twin surface copper-clad laminate; 5) Attaching photosensitive dry films to twin surfaces of the copper-clad laminate, and exposing and developing the dry films to perform patterns on twin surfaces of the copper-clad laminate, then etching the twin surfaces of the copper-clad laminate, thereby the first and the second copper column rows, as well as several separate upper and lower traces are made, wherein the top of the (n+1)th column of the first copper column row is connected to the top of the nth column of the second copper column row through one upper trace, and the bottom of the nth column of the first copper column row is connected to the bottom of the nth column of the second copper column row through one lower trace. This method features high efficiency.

### FIELD OF TECHNOLOGY

The present invention relates generally to the field of inductance coil, in particular to a three-dimensional inductance coil and a method for producing the same in printed circuit board.

### BACKGROUND

Inductance coil is an important component of electric circuit, and needs to be downsized with the higher integrality of circuit. Currently, a coil is usually made by wrapping copper wires with a diameter in the range of tens of microns to hundreds of microns, such coil features ineffective and large size. In addition, although it may be possible to produce a planar inductance coil in printed circuit board, in order to replace a three-dimensional solenoid coil, this has a great number of drawbacks, particularly of lower inductance values of the planar inductance coil. Moreover, it is inappropriate to produce a three-dimensional inductance coil by wrapping ultra-thin wires, because the wires are prone to breakage. Furthermore, it is also inappropriate to replace three-dimensional inductance coil with planar inductance coil, in terms of lower inductance values of the planar inductance coil.

The current inductance coil produced in a printed circuit board adopts the technique of equivalent inductance, using a planar inductance coil to replace a three-dimensional inductance coil. However, it is difficult for a planar inductance coil to have high inductance values. Generally for a long solenoid coil and a ratio of length to radius of the solenoid coil is larger than 40, then its inductance values can be calculated by the following formulas:

$$L = \frac{{μ}_{O} {N}^{2} π {r}^{2}}{l} \qquad ( 1 )$$

Wherein L is an inductance value of a solenoid coil, μₒ is a magnetic induction coefficient, N is coil turns, πr² is a cross-sectional areas of the solenoid coil, l is a length of the solenoid coil. As the coil produced in a printed circuit board is difficulty made in circular form, generally a cross-sectional area of the solenoid coil can be replaced by a cross-sectional area of a rectangle. Thereby,

$$L = \frac{{μ}_{O} {N}^{2} wh}{l} \qquad ( 2 )$$

Wherein w is a width of a rectangular solenoid coil, h is a height of a rectangular solenoid coil.

None of any method was used in a printed circuit board to produce three-dimensional inductance coil.

### SUMMARY

Therefore, it would be desirable to provide a method for producing three-dimensional inductance coil in printed circuit board to alleviate the above-described defects, so the coil has high efficiency and high inductance value.

In order to achieve the purpose, the present invention provides the following technical solution:

A method for producing a three-dimensional inductance coil in printed circuit board, comprising the steps of
1) Getting a twin surface copper-clad laminate where through-holes are made by drilling the copper-clad laminate bilaterally, to form two rows of through-holes on the twin surface copper-clad laminate;
2) Cleaning the interior of the through-holes to remove a residue after drilling;
3) Copper-plating the walls of the through-holes to form a copper layer thereon;
4) Filling the through-holes with copper fully to form a first copper column row and a second copper column row in the twin surface copper-clad laminate; and
5) Attaching photosensitive dry films to twin surfaces of the copper-clad laminate, and exposing and developing the dry films to perform patterns on twin surfaces of the copper-clad laminate, then etching the twin surfaces of the copper-clad laminate, thereby the first and the second copper column rows, as well as several separate upper and lower traces are made, wherein the top of the (n+1)th column of the first copper column row is connected to the top of the nth column of the second copper column row through one upper trace, and the bottom of the nth column of the first copper column row is connected to the bottom of the nth column of the second copper column row through one lower trace, where n is an integer and no less than 1.

The drilling process of the step 1) is a UV laser drilling process.

The cleaning process of the step 2) is a watery degumming process.

The copper layer of the step 3) is made by an electroless copper metallization process.

A thickness of the copper layer of the step 3) is 2-3 μm.

The filing process of the step 4) is a copper-plating process.

Preferably the two rows of through-holes are parallel one another.

Preferably, the intervals between two adjacent through-holes in the two rows of through-holes are identical.

In another aspect, the present invention provides a three-dimensional inductance coil produced by the above described method, and the coil comprises a first copper column row, a second copper column row, and several conductive upper and lower traces which are formed after an etching process to the twin surfaces of the copper-clad laminate; the top of the (n+1)th column of the first copper column row is connected to the top of the nth column of the second copper column row through the one upper trace, and the bottom of the nth column of the first copper column row is connected to the bottom of the nth column of the second copper column row through the one lower trace, where n is an integer and no less than 1.

Further, the two rows of through-holes are parallel one another, and the intervals between two adjacent through-holes in the two rows of through-holes are identical.

The present invention has the following advantages:

The three-dimensional inductance coil produced by the present invention features high efficiency and high inductance values, so as to avoid the defect that the wires are prone to breakage when wrapping wires to produce an inductance coil.

It is known that a planar coil requires large routing area, and the conventional method for producing planar inductance coil or rectangular planar involute inductance in printed circuit board may lead to low utilization rate of the board, the larger the coil the lower the utilization rate. However, three-dimensional inductance coils utilizes the z-axis of the board so as to save the routing area. In addition, the planar coil involves complicated design and calculation, e.g. in relation to stimulation and experiments. In contrast, the three-dimensional inductance coil is derived from conventional solenoidal inductance coils, which are calculated and designed easier. Moreover, as planar involute inductance coil is produced in one layer in printed circuit board, so planar parasitic inductance is hardly removed, that is, the eddy-current problem cannot be solved in terms of such native structure. However, three-dimensional inductance coil does not have this problem. Therefore, they have higher conductive quality and are widespread used. Furthermore, the planar inductance coil is in centimeter level, i.e. the largest diameter of a planar involute inductance coil generally is several centimeters, whereas the three-dimensional inductance coils produced in printed circuit hoard is in micron or millimeter level. In the event of coil having same size, the size of planar involute inductance coil will be greatly larger than the size of three-dimensional solenoid coil produced in printed circuit board.

### BRIEF DESCRIPTION

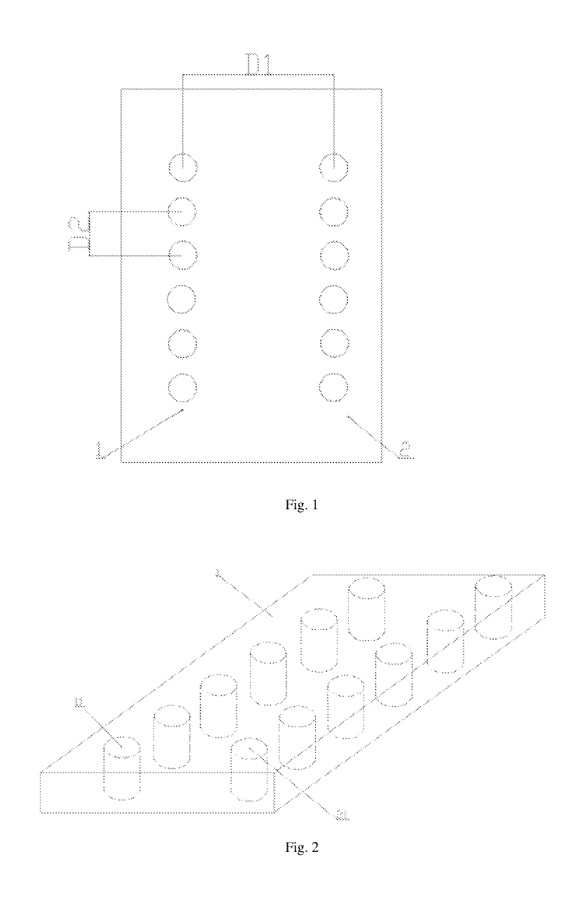

FIG. 1 is a schematic view of through-holes made in step 1) of embodiment of the present invention;

FIG. 2 is a schematic view of a twin surface copper-clad laminate having the through-holes;

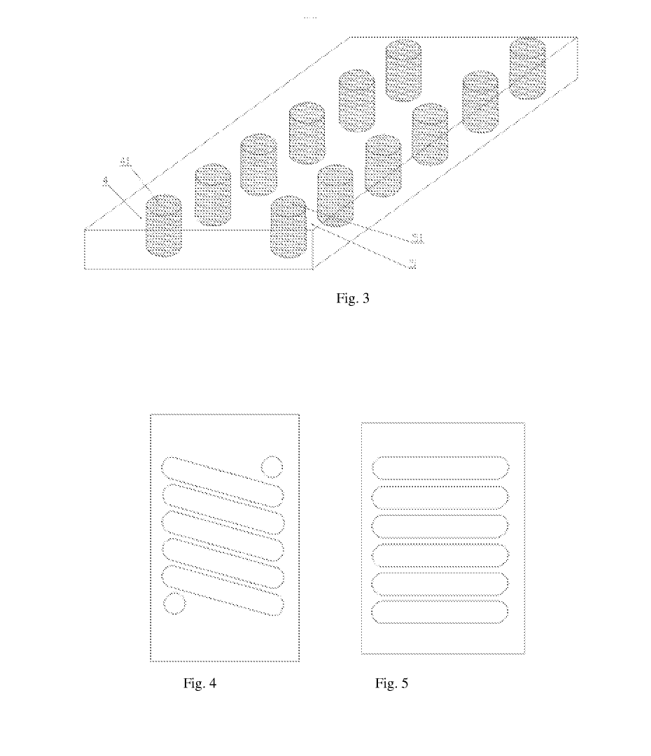

FIG. 3 is a schematic view of a twin surface copper-clad laminate having the through-holes which are plated and filled by copper;

FIG. 4 is a schematic view of a circuit on upper surface of the copper-clad laminate;

FIG. 5 is a schematic view of a circuit on lower surface of the copper-clad laminate;

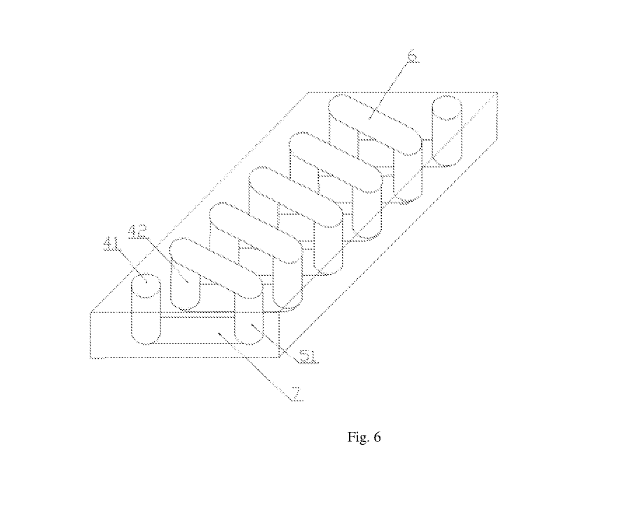

FIG. 6 is a schematic view of a three-dimensional inductance coil fabricated in embodiment of the present invention.

### DETAILED DESCRIPTION

The present invention will be described hereinafter with reference to the following embodiment and figures.

### Embodiment

A three-dimensional inductance coil is fabricated by the steps of:
1) Getting a twin surface copper-clad laminate where a substrate having thickness of 50 μm is sandwiched between twin surfaces made of copper foils having thickness of 18 μm and; two parallel rows of holes thereon can be designed by AutoCAD software, there would be a first row 1 and a second row 2, and each row involves six holes with a 50 μm diameter. As shown in FIG. 1, the intervals D2 between centers of two adjacent holes in the same row is 450 μm, and the intervals D1 between centers of two neighboring holes in the two rows is 4950 μm. As shown in FIG. 2, the corresponding two parallel rows of through-holes, i.e. a first row of through-holes 11, and a second row of through-holes 21, can be made on the copper-clad laminate 3 by UV laser drilling a copper-clad laminate 3 bilaterally;
2) Cleaning the interior of through-holes by watery degumming process to remove the residual gumming after drilling, and making the hole walls rough with surface roughness (Ra) of 500-1000 nm, so as to facilitate the subsequent electroless copper adhering and depositing;
3) Copper-plating the through-holes walls adopting electroless copper metallization technology which includes 30-second activation process, 10-second microetch process and 50-minute deposition process to ensure the thickness of plating copper on the through-holes walls at approximately 1 μm;
4) Copper-plating the through-holes until full of copper so as to form a first copper column row 4 and a second copper column row 5 in the copper-clad laminate, as shown in FIG. 3; the solution used in this copper-plating technology mainly comprises copper sulfate pentahydrate (220±20 g/L), sulphuric acid (50±10 g/L), chloride complex (50±10 ppm), accelerator (3620 A, 1.0±0.2 mL/L), inhibitor (3620 S, 15±3 mL/L), leveler (3620 L, 15±3 mL/L), wherein the accelerator, inhibitor and leveler is manufactured by Shanghai Xinyang Semiconductor Material Co. Ltd; and
5) Attaching photosensitive dry films to the twin surfaces of the copper-clad laminate, and a circuit pattern designed by AutoCAD software, as shown in FIGS. 4 & 5, is projected to the dry films by exposure machine, then the exposed dry film is developed and a circuit pattern is shown on the twin surfaces of the copper-clad laminate; after an etching process to the twin surfaces of the copper-clad laminate, three-dimensional inductance coil is therefore formed. In the etching process, a subtractive process or an semi-additive process is generally used, wherein subtractive process is a method that dry film protects circuit pattern from being etched while unprotected parts will be removed, and semi-additive process is a method that the dry film protects the parts except the circuit pattern while the circuit pattern is copper-plated such that the copper thickness in circuit pattern exceeds that of non-circuit pattern, then thin copper on the non-circuit pattern can be etched completely after an etching process, meanwhile as copper layer of the circuit pattern are perfectly thick and remain adequate, so as to form an inductance coil.

As shown in FIG. 6, the three-dimensional inductance coil fabricated by step 5 comprises the first copper column row 4, the second copper column row 5, five upper traces 6 positioned on upper surface of the copper-clad laminate and six lower traces 7 positioned on lower surface of the copper-clad laminate, wherein the top of the (n+1)th column of the first copper column row is connected to the top of the nth column of the second copper column row through one upper trace, and the bottom of the nth column of the first copper column row is connected to the bottom of the nth column of the second copper column row through one lower trace, where n is an integer and no less than 1, the solid lines in FIG. 6 depicts a three-dimensional inductance coil. For example, the top of the second column 42 of the first copper column row is connected to the top of the first column 51 of the second copper column row through one upper trace 6, and the bottom of the first column 41 of the first copper column row is connected to the bottom of the first column 51 of the second copper column row through one lower trace 7, and so on.

The present method for producing a three-dimensional inductance coil with six copper turns is effective, and meanwhile the coil produced by this method has higher inductance values as compared to the planar inductance coil with same turns.

The embodiment described hereinbefore is merely preferred embodiment of the present invention and not for purposes of any restrictions or limitations on the invention. It will be apparent that any non-substantive, obvious alterations or improvement by the technician of this technical field according to the present invention may be incorporated into ambit of claims of the present invention.

1. A method for producing a three-dimensional inductance coil in printed circuit board, comprising the steps of
1) Drilling through-holes on a twin surface copper-clad laminate bilaterally, to form two rows of through-holes on the twin surface copper-clad laminate;
2) Cleaning the interior of the through-holes to remove a residue after drilling;
3) Copper-plating the walls of the through-holes to form a copper layer thereon;
4) Filling the through-holes with copper fully to form a first copper column row and a second copper column row in the twin surface copper-clad laminate; and
5) Attaching photosensitive dry films to twin surfaces of the copper-clad laminate, and exposing and developing the dry films to perform patterns on twin surfaces of the copper-clad laminate, then etching the twin surfaces of the copper-clad laminate, thereby the first and the second copper column rows, as well as several separate upper and lower traces are made, wherein the top of the (n+1)th column of the first copper column row is connected to the top of the nth column of the second copper column row through one upper trace, and the bottom of the nth column of the first copper column row is connected to the bottom of the nth column of the second copper column row through one lower trace, where n is an integer and no less than 1.

2. The method of claim 1, wherein the drilling process of the step 1) is a UV laser drilling process; the cleaning process of the step 2) is a watery degumming process.

3. The method of claim 1, wherein the copper layer of the step 3) is made by an electroless copper metallization process.

4. The method of claim 1, wherein a thickness of the copper layer of the step 3) is 2-3 μm.

5. The method of claim 1, wherein the filing process of the step 4) is a copper-plating process.

6. The method of claim 1, wherein the two rows of through-holes are parallel one another, the intervals between two adjacent through-holes in the two rows of through-holes are identical.

7. A three-dimensional inductance coil comprising a first copper column row, a second copper column row, and several conductive upper and lower traces; the top of the (n+1)th column of the first copper column row is connected to the top of the nth column of the second copper column row through the one upper trace, and the bottom of the nth column of the first copper column row is connected to the bottom of the nth column of the second copper column row through the one lower trace, where n is an integer and no less than 1.

8. The three-dimensional inductance coil of claim 7, wherein the first and second copper column rows are parallel one another, the intervals between two adjacent columns in the first and second copper column rows are identical.

9. The three-dimension inductance coil of claim 7, wherein said three-dimension inductance coil is produced by the method of any of claim 1.

10. The three-dimension inductance coil of claim 7, wherein said three-dimension inductance coil is produced by the method of any of claim 2.

11. The three-dimension inductance coil of claim 7, wherein said three-dimension inductance coil is produced by the method of any of claim 3.

12. The three-dimension inductance coil of claim 7, wherein said three-dimension inductance coil is produced by the method of any of claim 4.

13. The three-dimension inductance coil of claim 7, wherein said three-dimension inductance coil is produced by the method of any of claim 5.

14. The three-dimension inductance coil of claim 7, wherein said three-dimension inductance coil is produced by the method of any of claim 6.

15. The three-dimension inductance coil of claim 8, wherein said three-dimension inductance coil is produced by the method of any of claim 1.

16. The three-dimension inductance coil of claim 8, wherein said three-dimension inductance coil is produced by the method of any of claim 2.

17. The three-dimension inductance coil of claim 8, wherein said three-dimension inductance coil is produced by the method of any of claim 3.

18. The three-dimension inductance coil of claim 8, wherein said three-dimension inductance coil is produced by the method of any of claim 4.

19. The three-dimension inductance coil of claim 8, wherein said three-dimension inductance coil is produced by the method of any of claim 5.

20. The three-dimension inductance coil of claim 8, wherein said three-dimension inductance coil is produced by the method of any of claim 6.
